(19) United States
(12) Patent Application Publication
(10) Pub. No.: US 2026/0096142 A1
(43) Pub. Date: Apr. 2, 2026

(54) TRANSISTOR SOURCE & DRAIN CONTACT STRUCTURES COMPRISING A LATERALLY SCALED CAP

(71) Applicant: Intel Corporation, Santa Clara, CA (US)

(72) Inventors: Deepti Krishnan, Hillsboro, OR (US); Amit Singh, Hillsboro, OR (US); Daniel J. Bahr, Portland, OR (US); Seda Cekli, Portland, OR (US); Christopher Nolph, Hillsboro, OR (US); Weiming Yeh, Portland, OR (US); Curtis Firby, Hillsboro, OR (US); Hsiao-An Sammy Wang, Vancouver, WA (US)

(73) Assignee: Intel Corporation, Santa Clara, CA (US)

(21) Appl. No.: 18/900,501

(22) Filed: Sep. 27, 2024

(51) Int. Cl. H01L 29/417; H01L 21/8234; H01L 27/088; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 84/013; H10D 84/038; H10D 84/83

(57) ABSTRACT

Transistor structures with source and drain contact metal structures comprising a lower portion of a first lateral dimension that is coupled with underlying channel material layers and an upper portion of a second lateral dimension that is coupled with an overlying via. The second lateral dimension is smaller than the first lateral dimension, enabling edge placement error associated with via patterning to be better accommodated. In some embodiments, an intervening dielectric liner is formed between an adjacent gate spacer dielectric material and the contact metal structures. The intervening dielectric liner may be formed, for example, by etching back a source or drain contact structure to form a self-aligned recess of a predetermined depth, forming a thin dielectric material layer upon sidewalls of the recess, and at least partially back filling a remainder of the recess with additional contact metal.

### BACKGROUND

For advanced integrated circuits (ICs), transistor terminal contact structures and conductive vias landing on such contact structures have a significant impact on transistor performance and transistor density. Although advanced lithographic patterning capabilities may enable a theoretical shrink in lateral dimensions of an electrical via coupling to transistor contact structures, the benefits of a such a via shrink may not be fully realized if there is not also a pathway to scale the contact structures.

Transistor contact architectures that can enable via scaling and/or reduce via-to-contact edge placement error constraints are therefore commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating fabrication of transistors with source and drain contact structures comprising a laterally scaled cap, in accordance with some embodiments;

FIGS. 2, 3, 4, 5, 6, 7, 8, 9, 10, and 11 are isometric views of transistor structures evolving as the methods illustrated in FIG. 1 are practiced, in accordance with some embodiments;

FIG. 12 illustrates a mobile computing platform and a data server machine employing an IC device with transistor structures that include source and drain contact structures comprising a laterally scaled cap, in accordance with some embodiments; and

FIG. 13 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. In one example, two compositions that are substantially the same, have only incidental chemical variation. As another example, composition that is substantially a first constituent means the composition may further include <1% of any other constituent. A composition that is substantially first and second constituents means the composition may further include <1% of any constituent substituted for either the first or second constituent.

In accordance with embodiments herein, integrated circuit transistor structures comprise a source and/or drain contact metal structure that includes a first portion of a first lateral dimension coupled with transistor channel material and a further includes a second portion of a second, smaller, lateral dimension that is coupled with an electrical via. For exemplary embodiments where the second portion is an upper portion of a source or drain contact structure, the second portion may be considered an electrically conductive “cap” that is laterally scaled from, and self-aligned to, underlying conductive contact material. Since the scaled cap of the contact structure is of reduced lateral dimensions, lateral spacing between the contact structure and adjacent features, such as a gate contact, is increased, improving edge placement error tolerances for subsequent via patterning. Furthermore, parasitic electrical capacitance between a source or drain contact structure and a gate contact structure may be reduced.

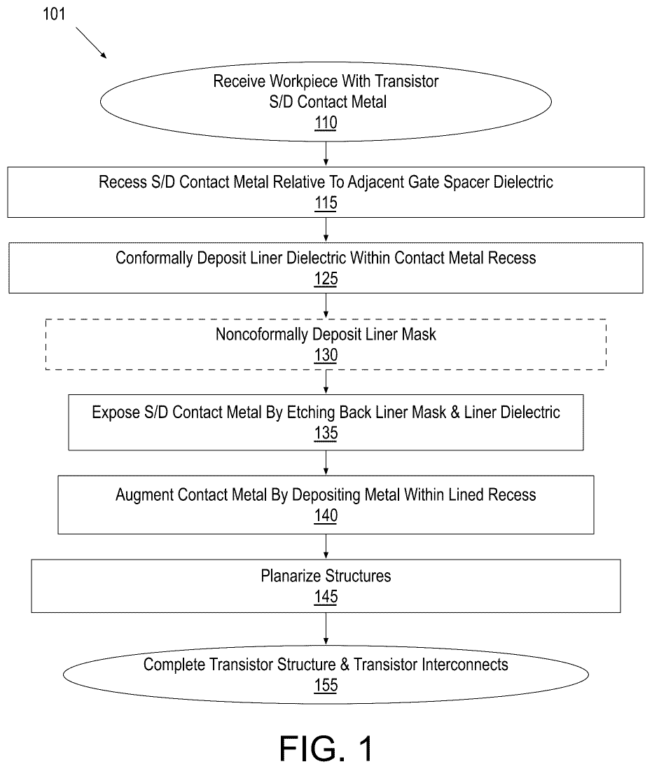

FIG. 1 is a flow diagram illustrating methods 101 for fabricating a transistor structure with source and drain contact structures comprising an electrically conductive cap of reduced lateral dimensions, in accordance with some embodiments. Methods 101 begin at input 110 with receipt of a workpiece including transistor structures comprising source and drain contact metal. In some examples, the workpiece received at input 110 comprises a 300-450 mm diameter wafer. The workpiece may include a substantially monocrystalline material and any number of transistor channel material layers over the monocrystalline material. Depending on the IC manufacturing process, various other transistor features may also be present on the workpiece, as received at input 110. For example, transistor channel semiconductor material may be present, source and drain semiconductor material may be present, gate electrodes may be present, etc. Accordingly, embodiments of methods 101 are not limited with respect to the incoming transistor architecture.

At block 115, source contact metal and/or drain contact metal is etched back relative to surrounding dielectric materials, such as an adjacent gate spacer dielectric material. In exemplary embodiments, the etch process practiced at block 115 is selective to the contact metal composition relative to surrounding dielectric material such that no masking is required and recession of the source and/or drain contact metal is self-aligned and/or confined to a particular contact structure. The etch process at block 115 advantageously retains a lower portion of a contact structure and forms a recess of some predetermined depth over the retained lower portion of the initial contact structure.

At block 125, the recess formed over the contact structure is laterally reduced to a smaller dimension by depositing a layer of dielectric material within the recess, for example adjacent to sidewalls of the surrounding dielectric material(s). The dielectric material may be conformally deposited, for example, to form a liner of a substantially uniform layer thickness within the recess. The liner layer thickness may be selected to laterally shrink the contact metal recess by a predetermined amount.

Source and drain contact metal below the liner dielectric deposited at block 125 is exposed at block 135, for example by anisotropically etching back the liner dielectric from a bottom of the recess. Depending on the composition of the dielectric liner deposited at block 125, the liner dielectric etch may benefit from the optional formation of a liner mask at block 130. For example, where etchback of the dielectric liner will not have sufficient selectively over underlying dielectric materials, such as a gate spacer dielectric material layer, deposition of a liner mask at block 130 can be advantageous. In other examples where the dielectric liner has a chemical composition that ensures good etch selectively to underlying dielectric materials, block 130 may be skipped.

In some exemplary embodiments where block 130 is practiced, a self-aligned liner mask is formed with a non-conformal thin film deposition process, which may form a liner mask material at a lower rate within the contact metal recess than over surrounding areas of an IC. As a result, the dielectric liner outside of the contact metal recess may be protected by the liner mask material during etchback of the liner dielectric at block 135.

Contact metal exposed with a bottom of the recess is augmented though the deposition of additional “capping” contact metal, at block 140. Contact metal may be augmented with any suitable metal deposition process(es), that at least partially backfills a remainder of the contact metal recess not occupied by the liner dielectric material. Accordingly, the backfilled contact metal will have a lateral dimension (e.g., a width or diameter) that is reduced relative to the underlying contact metal structure that was recessed at block 115. In some examples, the metal deposited at block 140 has substantially the same chemical composition as the underlying source and drain contact metal such that the resulting capped contact structure has a substantially homogenous composition across an interface between upper and lower portions of the contact structure.

At block 145, overburden from metal deposition at block 140 and/or the liner mask deposition at block 130 and/or the liner dielectric deposition at block 125 may be removed, for example with a planarization process. The planarization process may, for example, leave a top surface of a contact metal cap at some predetermined height above an underlying transistor channel layer. Methods 101 may then end at output 155 where the transistor structure is completed and transistor interconnected with various levels of metallization vias and lines. A metallization via formed at output 155 may, for example, land on (or otherwise intersect) the contact metal cap. The smaller lateral dimensions of the contact metal cap may enable a source/drain via to also have scaled (reduced) lateral dimensions and/or be patterned with less restrictive edge placement error constraints.

In methods 101, the metal deposited at block 140 may function as an electrically conductive cap self-aligned to the underlying contact structure and/or channel material layers so that a lower portion of the contact metal is assured to be electrically coupled to the channel material while an upper portion of the contact metal is dimensionally scaled to interface with a dimensional scaled electrical via. Accordingly, transistor structures, such as channel ribbons or wires (RoWs) and gate structures, etc. may be fabricated more independently from backend metallization structures.

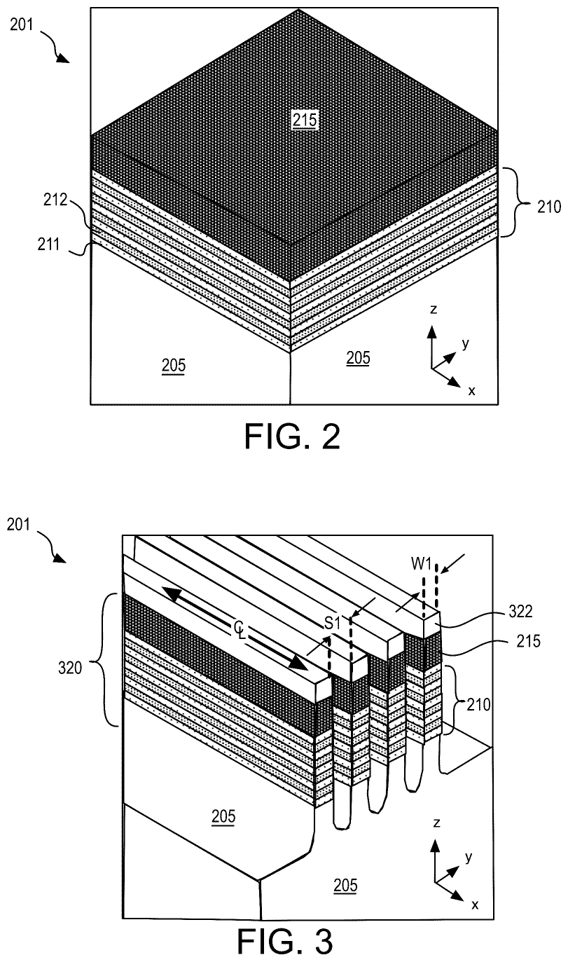

FIG. 2-11 illustrate isometric views of transistor structures evolving as the methods 101 are practiced, in accordance with some exemplary embodiments. The depicted transistor structures further highlight structural features associated with the practice of methods 101. However, the practice of methods 101 need not result in all the structures exactly as illustrated in FIG. 2-11. Other implementations of methods 101 are also possible, and not all aspects of methods 101 need be practiced by all implementations of methods 101.

In the example illustrated in FIG. 2, a workpiece portion 201 comprises a dielectric material 215 over a transistor channel material stack 210 that further includes a plurality of bi-layers. Each bilayer may comprise a sacrificial material 211 and a channel material 212. The number of bi-layers may vary with implementation. Channel material 212 may have any composition suitable for a channel of a field effect transistor (FET). In some examples, channel material 212 is substantially silicon. In other embodiments, channel material 212 comprises germanium (e.g., Si₁₋ₓGe_{X}, Ge₁₋ₓSn_{X}, or substantially pure Ge). In some embodiments, channel material 212 includes a transition metal and a chalcogen. The transition metal may be any transition metal such as any element of groups 4 through 11, the group 3 elements scandium and yttrium, and the inner transition metals (e.g., f-block lanthanide and actinide series). Notable transition metals are molybdenum and tungsten. The chalcogen may be sulfur, selenium, and tellurium. In still other embodiments, channel material 212 comprises one or more metals and oxygen (i.e., metal oxide semiconductor), such as, but not limited to, Indium, gallium zinc oxide (IGZO).

Channel material 212 is advantageously crystalline. Although the crystalline semiconductor includes polycrystalline thin film material, in some embodiments channel material 212 is substantially monocrystalline. In some examples where channel material 212 is substantially pure silicon, the crystallinity of channel material 212 is cubic with a top surface having a crystallographic orientation of (100), (111), or (110). However, other crystallographic orientations are also possible. In other examples, channel material 212 may be polycrystalline or amorphous, for example in certain metal chalcogen and/or metal oxide embodiments.

Sacrificial material 211 has a different composition than channel material 212. In some examples, sacrificial material 211 has more germanium than channel material 212. For example, where channel material 212 is predominantly silicon, sacrificial material 211 is Si₁₋ₓGe_{X}, and X may be advantageously between 0.3-0.35. In other embodiments, sacrificial material 211 has less germanium than channel material 212. For example, where the channel material 212 is Si₁₋ₓGe_{X}, sacrificial material 211 may be predominantly silicon. In other embodiments where channel material 212 is a first metal chalcogenide, sacrificial material 211 may be a second metal chalcogenide or a metal oxide, for example.

Dielectric material 215 may have any composition known to be suitable as a hardmask for patterning channel material stack 210. In some examples, dielectric material 215 is silicon oxide (SiO), silicon nitride (SiN), or silicon oxynitride, (SiON). Although only one layer is illustrated in FIG. 2, dielectric material 215 may comprise one or more material layers having a total thickness, for example in the range of 5-50 nm.

As further illustrated in FIG. 3, transistor fin lines 320 are patterned into the channel material layers(s) and into an overlying dielectric material. The fin lines may extend any length along a first dimension and have a width in a second, orthogonal dimension. Any lithographic masking process and material etch process(es) may be practiced to form fin lines 320. Each fin line 320 comprises channel material stack 210 and mask material 215. Each fin line 320 may also comprise a sub-fin portion of underlying substrate material 205. In the illustrated example, fin lines 320 are substantially parallel and extend laterally a longitudinal length in the x-dimension. An arrow demarks a centerline (CL) of one fin line 320 that is coincident with the illustrated x-axis. A lithographic mask 322 defined fin lines 320 to have a first lateral width W1 coincident with the y-axis (i.e., orthogonal to the direction of the longitudinal centerline). Laterally adjacent fin lines 320 are separated by a space S1. Line width W1 and space S1 define a y-dimensional pitch of fin lines 320.

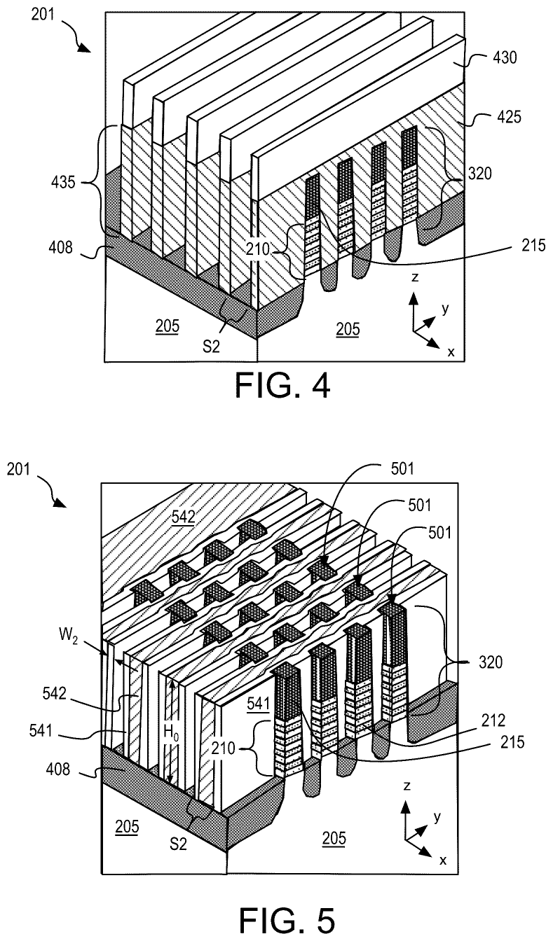

As illustrated in FIG. 4, fin lines 320 are bifurcated into segments with each segment located over a transistor channel region. This bifurcation may be with a second lithographic patterning process defining gate mandrel lines 435 that in this example are substantially orthogonal to fin lines 320. At this point in fabrication, workpiece portion 201 includes an isolation material 408 between fin lines 320. To form gate mandrel lines 435, a gate mandrel material 425 has been deposited over fin lines 320 and etched according to a photolithographically patterned mask 430. In the illustrated example, gate mandrel lines 435 are substantially parallel and extend laterally over a longitudinal length coincident with the depicted y-axis. Each gate mandrel line 435 has a transverse length that is over an underlying segment of dielectric material 215 and, below that, a length of channel material stack 210. Between adjacent gate mandrel lines 435 is a space S2.

With each gate mandrel line 435 protecting underlying channel material one or more gate spacer dielectric material layers may be deposited over gate mandrel lines 435. Fin lines 320 may also be bifurcated a distance beyond each gate mandrel line 435, for example as masked by a lateral width W2 of the one or more gate spacer dielectric material layers adjacent to a sidewall of each gate mandrel line 435. Optionally, sacrificial material of stack 210 that is exposed within space S2 may be recess etched, for example with an isotropic chemical process selective to the sacrificial material that forms a dimple under gate spacer dielectric material layers. Such a dimple may then be backfilled with an additional spacer dielectric material layer.

Source and drain semiconductor material (not depicted) may be deposited or epitaxially grown within spaces S2, for example in direct contact with opposite ends of transistor channel material layers within stack 210 on opposite sides of each gate mandrel line 435. Any technique(s) may be practiced to form source and drain regions, which may comprise any semiconductor material having a high concentration of impurities that impart either p-type or n-type conductivity. Following the formation of source and drain structures, source and/or drain contact metal may be further deposited within space S2. The contact metal may form a structure comprising one or more layers. For contact structures with more than one metal layer, a first contact metal layer may have a chemical composition offering low contact resistance to the source and/or drain semiconductor material while a second contact metal layer is free to have a second chemical composition, such as tungsten or titanium, etc.

In the example further illustrated in FIG. 5, gate mandrel lines 435 have been removed in preparation for the formation of a transistor gate stack. A gate spacer dielectric layer 541 remains within space S2, which in this example is co-planar with a top surface of dielectric material 215. Although a gate spacer dielectric layer 541 may have any composition, in exemplary embodiments gate spacer dielectric layer 541 has a different chemical composition than that of dielectric material 215. As further illustrated in FIG. 5, a contact metal structure portion 542 has an initial height H₀ relative to a reference plane of substrate 205, or an alternative reference plane, such as that of a first (lowest) one of channel material layers 212. Initial height H₀ may be defined, for example, by a planarization process that leaves contact metal structure portion 542 co-planar with spacer dielectric layer 541 and/or the top surface of dielectric material 215.

Removal of the gate mandrel lines exposes mask material segments 501 of mask material 215 so that a gate stack comprising a gate insulator and a gate (electrode) may be formed adjacent to the channel material layers. Sacrificial material layers within stack 210 may be removed from between channel material layers, for example with a selective chemical etch process. Any suitable gate stack may then be formed over one or more surfaces of the channel material.

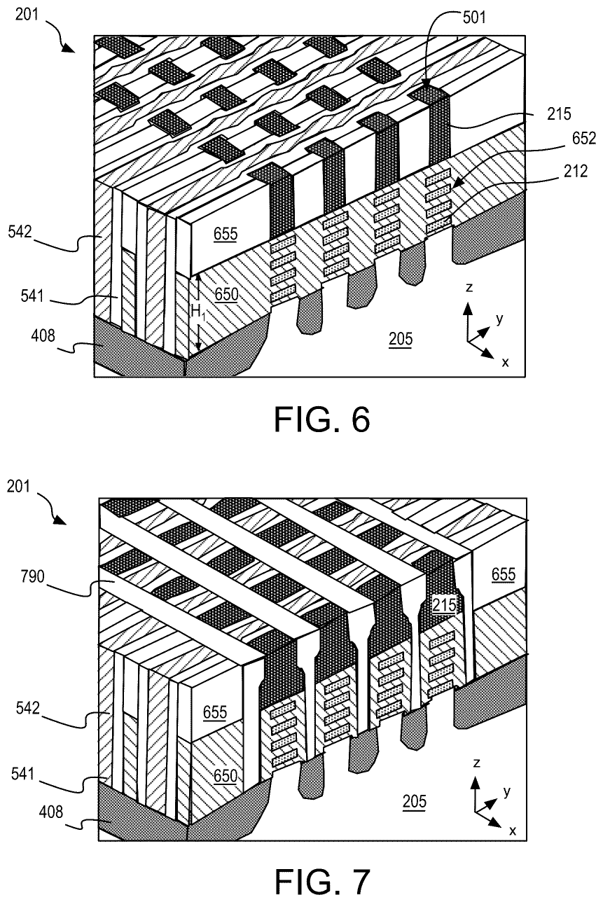

In the example further illustrated in FIG. 6, gate material 650 occupies a region between adjacent ones of gate spacer material layer 541. As shown, gate material 650 backfills channel regions where sacrificial material has been removed from between layers of channel material 212. In addition to gate material 650, a gate stack may include one or more layers of gate insulator 652. Gate insulator 652 may include a high-k (e.g., >9) dielectric material layer, such as one including oxygen and one or more metals, for example. Gate material 650 may similarly comprise one or more material layers, such as a workfunction material layer and a bulk fill material layer. A bulk fill material layer may have any composition, such as platinum, molybdenum, tungsten, titanium, and nitrides such as titanium nitride, tungsten nitride, etc. Gate material 650 may be deposited and planarized with a surface of dielectric material 215 and/or gate spacer material layer 541, and/or contact metal structure portion 542. In the example illustrated in FIG. 6, after planarization gate material 650 is recess etched to a height H₁ relative to a reference plane of substrate 205, or an alternative reference plane, such as that of one of channel material layers 212. The recessed gate material 650 may be capped with a dielectric material 655 that occupies regions from where gate material 650 was recessed. Dielectric material 655 may have any composition. In some embodiments, dielectric material 655 comprises more carbon, more oxygen, less silicon, or less nitrogen than dielectric material 215. As one example, mask material 655 is amorphous carbon (α-carbon).

In the example illustrated in FIG. 7, a width of the gate material 650 is defined. This “gate-cut” patterning process may, for example, pattern lines substantially parallel to the fin lines. Any etch process capable of removing gate material 650 (and dielectric material 655, if present) may be practiced to form trenches located within spaces between adjacent transistors. The gate cut trenches may then be at least partially backfilled with a dielectric material 790, and advantageously planarized with dielectric material 215 and/or contact metal structure 542. Dielectric material 790 may be SiO, SIN, SiON, or low-k dielectric material, for example.

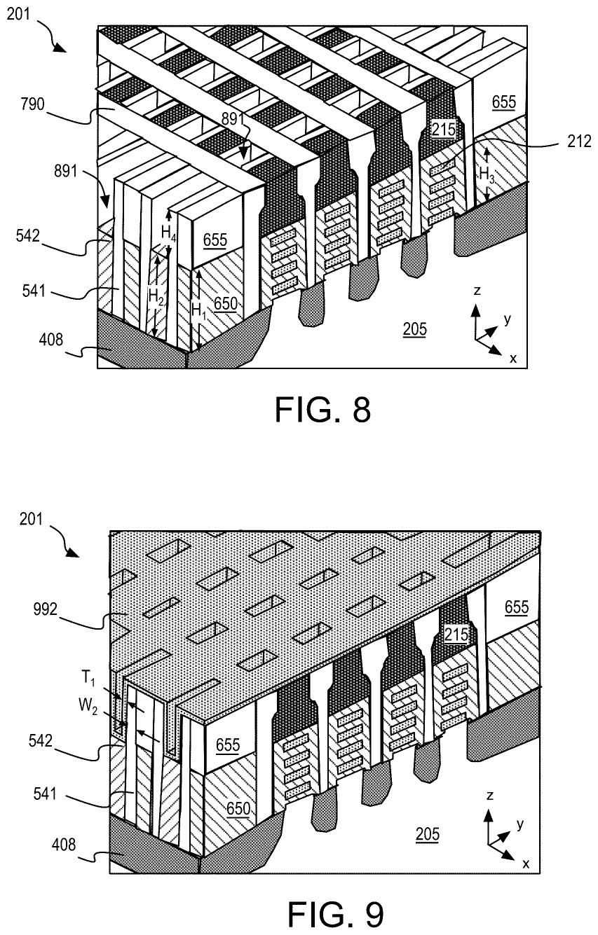

Transistor structure fabrication continues with recessing the source and drain contact metal structures. As illustrated in FIG. 8, contact metal structure portion 542 is etched back from initial height H₀ to a recessed height H₂ above the reference plane of substrate 205. Height H₂ may vary with implementation, but height H₂ is advantageously greater than height H₃ of the stack of channel material layers 212 (e.g., relative to a same reference plane). Accordingly, source and drain semiconductor material may not be exposed within contact metal recesses 891. In the illustrated example, contact metal structure portion 542 is etched back to a recessed height H₂ that is approximately equal to gate material height H₁ so that contact metal structure portion 542 and gate material 650 are approximately co-planar. Any selective etch process may be employed to recess contact metal structure portion 542 by the predetermined height reduction H₄. For example, in embodiments where contact metal structure portion 542 comprises tungsten, a tungsten etch process may be practiced for a timed duration to form recesses 891.

As further illustrated in FIG. 9, a dielectric liner material 992 is deposited within the contact metal recesses 891. As shown, dielectric liner material 992 has a substantially conformal as-deposited thickness, accumulating a lateral thickness T₁ on sidewalls of gate spacer dielectric layer 541. Thickness T₁ may vary with implementation and may range from 5-15 nm, for example. In some embodiments, liner thickness T₁ is less than a lateral width W2 of gate spacer dielectric layer 541. Lateral dimensions of contact metal recesses 891 may therefore be reduced by twice thickness T₁ within the x-dimension as well as the y-dimension. The chemical composition of dielectric liner material 992 may vary with implementation. In some embodiments, dielectric liner material 992 has a different composition than of any underlying material, such as gate spacer dielectric layer 541. In other embodiments, dielectric liner material 992 has a composition that is the same as that of one or more underlying materials. For example, dielectric liner material 992 may have the same composition as at least one of dielectric material 215, gate spacer dielectric material layer 541, dielectric material 655, or dielectric material 790.

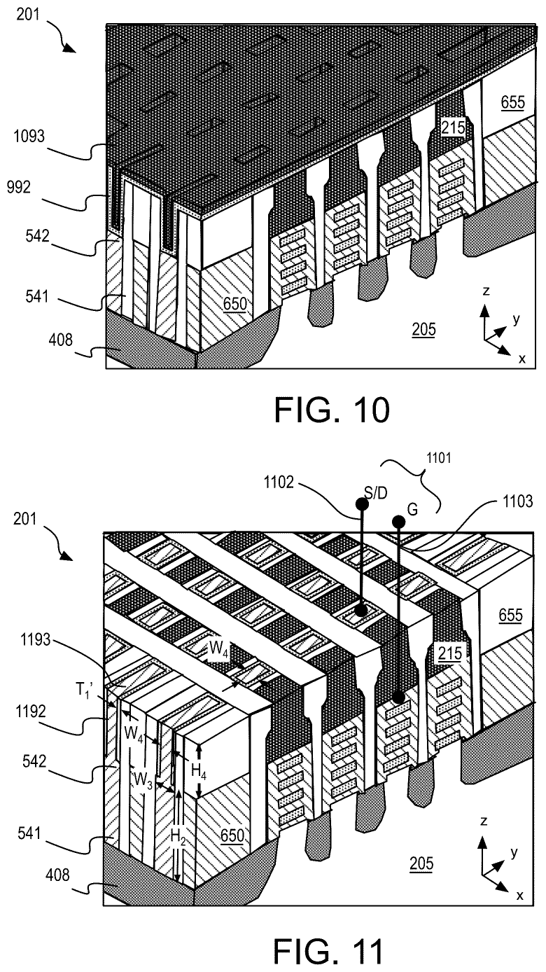

Dielectric liner material 992 is then etched back from a bottom of recesses 891 to expose the underlying contact metal structure portion 542. Depending on the composition of dielectric liner material 992, the etch back may be a blanket etch or an additional material layer be deposited over dielectric liner material 992 prior to the etch back process to mask portions of dielectric liner material 992 outside of recesses 891. FIG. 10, for example, illustrates a non-conformal deposition of a mask material 1093. Mask material 1093 is deposited more rapidly on open areas than within the topography of recesses 891 such that a protective “helmet” accumulates on portions of dielectric liner material 992 in regions beyond recesses 891. Dielectric liner material 992 may then be etched back to expose contact metal structure 542 at a bottom of recesses 891 without exposing top surfaces of adjacent transistor structures.

As further illustrated in FIG. 11, the etch back of dielectric liner material 992 forms a contact metal structure liner 1192 adjacent to (and in direct contact with) a sidewall of gate spacer dielectric material layer 541. Following the etch back, contact metal structure liner 1192 has a lateral sidewall liner thickness of T₁′, which may vary as a function of the as-deposited thickness T₁ and as a function of the etch process(es). In some examples where the as-deposited thickness T₁ is 5-15 nm, the post-etch liner thickness T₁′ is in the range of 0.3-5 nm. A remainder of recess 891 is then backfilled with additional contact metal. The additional contact metal may, for example, have the same composition as the contact metal that was recessed. Following deposition of the supplemental contact metal, a planarization process may be performed to remove any contact metal overburden, mask material 1093 and dielectric liner material 992 from regions outside of the contact metal recesses 891. Following planarization, an electrically conductive contact metal cap, pillar, or post portion 1193 is retained within recesses 891 and is spaced apart from gate spacer dielectric material layer 541 by contact metal dielectric liner 1192. The contact metal cap portion 1193 may have approximately height H₄, adding to the underlying contact structure portion 542 of height H₂. Contact metal cap portion 1193 has a lateral dimension (e.g., width) W₄ that is less than the corresponding lateral dimension (e.g., width) W₃ of the underlying contact metal structure portion 542, for example by approximately twice the post-etch liner thickness T₁. Accordingly, in some examples width W₄ is 0.6-10 nm smaller than width W₃. Contact metal cap portion 1193 may similarly have a lateral dimension (e.g., length) that is less than the corresponding second lateral dimension of the underlying contact metal structure portion 542 by approximately twice the post-etch liner thickness T₁′.

For each transistor structure 1101, source and/or drain contact metal structures comprise an underlying contact metal structure portion 542 and a contact metal cap portion 1193. The two contact metal structure portions may, for example, have the same chemical composition such that the contact metal is substantially homogenous across an interface between heights H₂ and H₄. In the illustrated embodiment where the resulting contact metal structure has a total height of H2+H4, a source and/or drain contact via 1102 may be landed upon a top surface of the source and drain contact metal structure that is of significantly reduced lateral dimensions relative to dimensions of the underlying portion of the contact metal structure. The reduce lateral dimensions may, for example, facilitate the formation of scaled vias to the source and/or drain contact metal structures. The source and drain contact metal structures may also be of a significantly different height (e.g., taller) than a corresponding height of gate material 650. Accordingly, a depth of a gate via 1103 landing on gate material 650 may be greater than the depth of source and drain contact vias 1102 landing on contact metal cap portion 1193.

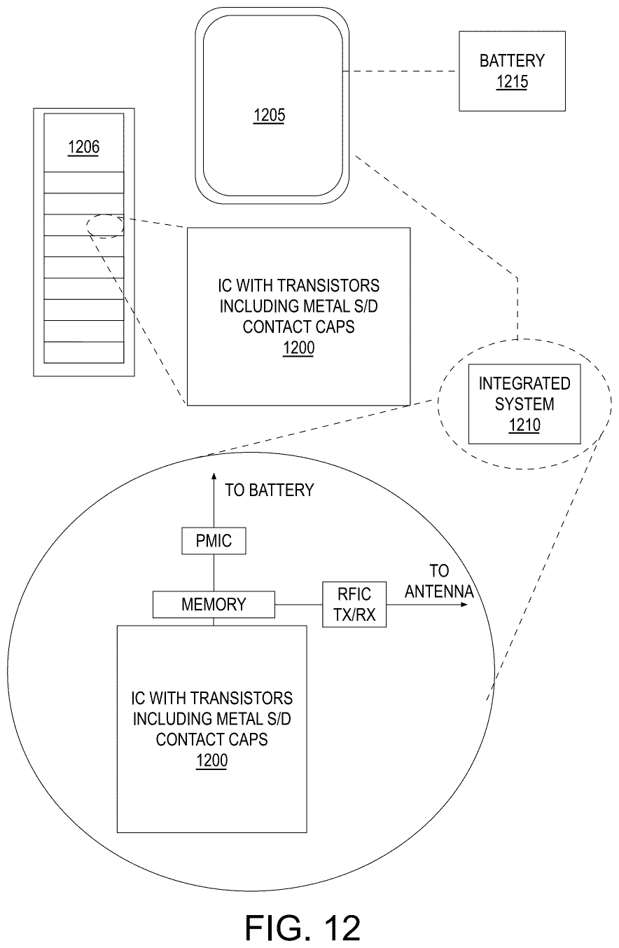

The transistor structures described above may be employed in a wide range of IC devices and further integrated in a wide range of computer-based applications. FIG. 12 illustrates a mobile computing platform 1205 and a server machine 1206, each employing a packaged IC die including transistors with source/drain contact structures that have a laterally scaled metal cap, for example as described elsewhere herein. Server machine 1206 may be any commercial server, for example including any number of high-performance computing platforms disposed within a rack and networked together for electronic data processing, which in the exemplary embodiment includes a packaged IC die comprising transistors with source/drain contact structures that have a laterally scaled metal cap, for example as described elsewhere herein.

The mobile computing platform 1205 may be any portable device configured for each of electronic data display, electronic data processing, wireless electronic data transmission, or the like. For example, the mobile computing platform 1205 may be any of a tablet, a smart phone, laptop computer, etc., and may include a display screen (e.g., a capacitive, inductive, resistive, or optical touchscreen), an integrated system 1210, and a battery 1215.

As illustrated in the expanded view of FIG. 12, one or more of a power management integrated circuit (PMIC) or RF (wireless) integrated circuit (RFIC) including a wideband RF (wireless) transmitter and/or receiver may be further coupled to IC 1200. A PMIC may perform battery power regulation, DC-to-DC conversion, etc., and so has an input coupled to battery 1215 and an output providing a current supply to other functional modules. An RFIC may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

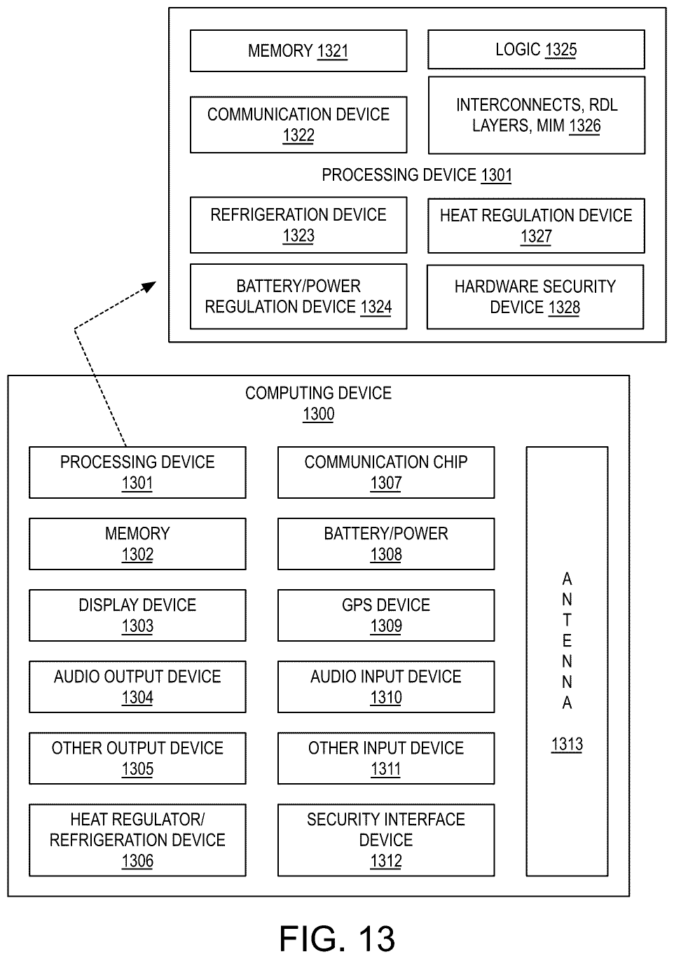

FIG. 13 is a block diagram of a cryogenically cooled computing device 1300 in accordance with some embodiments. For example, one or more components of computing device 1300 may include transistors with source/drain contact structures that have a metal cap, for example as discussed elsewhere herein. A number of components are illustrated in FIG. 13 as included in computing device 1300, but any one or more of these components may be omitted or duplicated, as suitable for the application. In some embodiments, some or all of the components included in computing device 1300 may be attached to one or more printed circuit boards (e.g., a motherboard). In some embodiments, various ones of these components may be fabricated onto a single system-on-a-chip (SoC) die. Additionally, in various embodiments, computing device 1300 may not include one or more of the components illustrated in FIG. 13, but computing device 1300 may include interface circuitry for coupling to the one or more components. For example, computing device 1300 may not include a display device 1303, but may include display device interface circuitry (e.g., a connector and driver circuitry) to which display device 1303 may be coupled.

Computing device 1300 may include a processing device 1301 (e.g., one or more processing devices). As used herein, the term processing device or processor indicates a device that processes electronic data from registers and/or memory to transform that electronic data into other electronic data that may be stored in registers and/or memory. Processing device 1301 may include a memory 1302, a communication device 1322, a refrigeration/active cooling device 1323, a battery/power regulation device 1324, logic 1325, interconnects 1326 (i.e., optionally including redistribution layers (RDL) or metal-insulator-metal (MIM) devices), a heat regulation device 1327, and a hardware security device 1328.

Processing device 1301 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1301 may include a memory 1302, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1321 includes memory that shares a die with processing device 1301. This memory may be used as cache memory and may include embedded dynamic random-access memory (eDRAM) or spin transfer torque magnetic random-access memory (STT-M RAM).

Computing device 1300 may include a heat regulation/refrigeration device 1306. Heat regulation/refrigeration device 1306 may maintain processing device 1301 (and/or other components of computing device 1300) at a predetermined low temperature during operation. This predetermined low temperature may be any temperature discussed elsewhere herein.

In some embodiments, computing device 1300 may include a communication chip 1307 (e.g., one or more communication chips). For example, the communication chip 1307 may be configured for managing wireless communications for the transfer of data to and from computing device 1300. The term “wireless” and its derivatives may be used to describe circuits, devices, systems, methods, techniques, communications channels, etc., that may communicate data through the use of modulated electromagnetic radiation through a nonsolid medium.

Communication chip 1307 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). Communication chip 1307 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1307 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1307 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1307 may operate in accordance with other wireless protocols in other embodiments. Computing device 1300 may include an antenna 1313 to facilitate wireless communications and/or to receive other wireless communications (such as AM or FM radio transmissions).

In some embodiments, communication chip 1307 may manage wired communications, such as electrical, optical, or any other suitable communication protocols (e.g., the Ethernet). As noted above, communication chip 1307 may include multiple communication chips. For instance, a first communication chip 1307 may be dedicated to shorter-range wireless communications such as Wi-Fi or Bluetooth, and a second communication chip 1307 may be dedicated to longer-range wireless communications such as GPS, EDGE, GPRS, CDMA, WiMAX, LTE, EV-DO, or others. In some embodiments, a first communication chip 1307 may be dedicated to wireless communications, and a second communication chip 1307 may be dedicated to wired communications.

Computing device 1300 may include battery/power circuitry 1308. Battery/power circuitry 1308 may include one or more energy storage devices (e.g., batteries or capacitors) and/or circuitry for coupling components of computing device 1300 to an energy source separate from computing device 1300 (e.g., AC line power).

Computing device 1300 may include a display device 1303 (or corresponding interface circuitry, as discussed above). Display device 1303 may include any visual indicators, such as a heads-up display, a computer monitor, a projector, a touchscreen display, a liquid crystal display (LCD), a light-emitting diode display, or a flat panel display, for example.

Computing device 1300 may include an audio output device 1304 (or corresponding interface circuitry, as discussed above). Audio output device 1304 may include any device that generates an audible indicator, such as speakers, headsets, or earbuds, for example.

Computing device 1300 may include an audio input device 1310 (or corresponding interface circuitry, as discussed above). Audio input device 1310 may include any device that generates a signal representative of a sound, such as microphones, microphone arrays, or digital instruments (e.g., instruments having a musical instrument digital interface (MIDI) output).

Computing device 1300 may include a global positioning system (GPS) device 1309 (or corresponding interface circuitry, as discussed above). GPS device 1309 may be in communication with a satellite-based system and may receive a location of computing device 1300, as known in the art.

Computing device 1300 may include another output device 1305 (or corresponding interface circuitry, as discussed above). Examples include an audio codec, a video codec, a printer, a wired or wireless transmitter for providing information to other devices, or an additional storage device.

Computing device 1300 may include another input device 1311 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1300 may include a security interface device 1312. Security interface device 1312 may include any device that provides security measures for computing device 1300 such as intrusion detection, biometric validation, security encode or decode, managing access lists, malware detection, or spyware detection. In some examples, security interface device 1312 comprises OTP ROM further including a via MIM fuse, for example as described elsewhere herein.

Computing device 1300, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments described above, but can instead be practiced with modification and alteration without departing from the scope of the appended claims. For example, the above embodiments may include specific combinations of features as further provided below.

In first examples, an apparatus comprises a transistor channel layer, a gate adjacent to the channel layer, a gate spacer material layer adjacent to a sidewall of the gate, an da source or drain contact metal structure coupled to the channel layer. A lower portion of the source or drain contact metal structure is in direct contact with the gate spacer material layer. An upper portion of the source or drain contact metal structure is in direct contact with an intervening dielectric material that is between the gate spacer material layer and source or drain contact metal structure.

In second examples, for any of the first examples, the transistor channel layer is one of a plurality of channel layers in a stack of the channel layers, the gate is adjacent to, and between, individual ones of the channel layers; the source and drain contact metal structure is coupled to each of the channel layers, and within a first plane passing through a pair of source and drain contact metal structures, the upper portion of each of the source and drain contact metal structures has a first lateral width while the lower portion of each of the source and drain contact metal has a second lateral width, larger than the first lateral width.

In third examples, for any of the second examples the second lateral width is larger than the first lateral width by twice a lateral thickness of the intervening dielectric material.

In fourth examples, for any of the third examples within a second plane orthogonal to the first plane, the upper portion of each of the pair of source and drain contact metal structures has a first lateral length and the lower portion of the source and drain contact metal structures has a second lateral length, larger than the first lateral length.

In fifth examples, for any of the second through fourth examples the gate comprises a metal structure of a first height above a first the channel material layers. The lower portion of the pair of source and drain contact metal structures has a second height above the first of the channel material layers. The second height is no greater than the first height.

In sixth examples, for any of the first examples the gate spacer material layer extends to a third height above the first of the channel material layers, and the upper portion of the pair of source and drain contact metal structures have at least the third height.

In seventh examples, for any of the sixth examples the apparatus comprises a gate capping dielectric material over the gate structure and having at least the third height, wherein the gate spacer material is between a sidewall of the gate capping dielectric material and the intervening dielectric material.

In eighth examples, for any of the seventh examples a top surface of the gate capping dielectric material is coplanar with a top surface of the upper portion of the source and drain contact metal structures.

In ninth examples, for any of the first through eighth examples the gate spacer material has a first dielectric composition and the intervening dielectric material has a second dielectric composition comprising more carbon or nitrogen than the first dielectric composition.

In tenth examples, for any of the first through ninth examples the lower and upper portions of the source or drain contact metal structure have substantially the same chemical composition.

In eleventh examples, for any of the first through tenth examples the apparatus further comprises a first via contacting the gate and a second via contacting the source or drain contact metal structure, wherein the first via is deeper than the second via.

In twelfth examples, an integrated circuit structure comprises a plurality of transistor channel layers and a gate adjacent to, and between, individual ones of the channel layers. The circuit structure comprises a gate spacer material layer adjacent to a sidewall of the gate and a source or drain contact metal structure coupled to the channel layers. A lower portion of the source or drain contact metal structure has a first lateral width and an upper portion of the source or drain contact metal structure has a second lateral width. The second lateral width is smaller than the first lateral width by at least a thickness of an intervening dielectric material that is between the gate spacer material layer and upper portion of the source or drain contact metal structure.

In thirteenth examples, for any of the twelfth examples the second lateral width is smaller than the first lateral width by at least twice the thickness of the intervening dielectric material. The gate comprises a metal structure of a first height above a first the channel material layers. The lower portion of the source or drain contact metal structure has a second height above the first of the channel material layers and the second height is no greater than the first height.

In fourteenth examples, for any of the thirteenth examples the circuit structure further comprises a first via of a first depth in contact with the metal structure of the gate at the first height and a second via of a second depth in contact with the upper portion of the source or drain contact metal, wherein the first depth is greater than the second depth.

In fifteenth examples, for any of the twelfth through fourteenth examples the intervening dielectric material has a different chemical composition than the gate spacer material layer.

In sixteenth examples, for any of the twelfth through fifteenth examples the intervening dielectric material has lateral thickness less than a lateral distance between the intervening dielectric material and the sidewall of the gate.

In seventeenth examples a method comprises receiving a workpiece comprising a metal gate structure adjacent to, and between, a plurality of stacked channel material layers. The method comprises exposing a sidewall of a gate spacer material layer adjacent to a sidewall of the metal gate structure by recessing a top surface of a pair of source and drain contact metal structures. The method comprises depositing a dielectric material liner upon the sidewall of the gate spacer material. The method comprises exposing the top surface of the pair of source and drain contact metal structures by anisotropically etching the dielectric material liner. The method comprises augmenting the pair of source and drain contact metal structures by depositing additional contact metal in direct contact with the top surface of the pair of source and drain contact metal structures and in direct contact with a sidewall of the dielectric material liner.

In eighteenth examples, for any of the seventeenth examples the method comprises depositing a mask material over the dielectric material liner before anisotropically etching the mask material and the dielectric material liner.

In nineteenth examples, for any of the seventeenth through eighteenth examples the method comprises planarizing a top surface of the source and drain contact metal with a top surface of a dielectric material over the metal gate structure.

In twentieth examples, for any of the seventeenth through nineteenth examples the pair of source and drain contact metal structures comprise one or more metals and depositing the additional contact metal comprises depositing the same one or more metals.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should, therefore, be determined with reference to the appended claims, along with the full scope of equivalents to which such claims are entitled.

What is claimed is:

1. An apparatus, comprising:
a transistor channel layer;
a gate adjacent to the channel layer;
a gate spacer material layer adjacent to a sidewall of the gate; and
a source or drain contact metal structure coupled to the channel layer, wherein:
a lower portion of the source or drain contact metal structure is in direct contact with the gate spacer material layer; and
an upper portion of the source or drain contact metal structure is in direct contact with an intervening dielectric material that is between the gate spacer material layer and source or drain contact metal structure.

2. The apparatus of claim 1, wherein:
the transistor channel layer is one of a plurality of channel layers in a stack of the channel layers;
the gate is adjacent to, and between, individual ones of the channel layers; and
within a first plane passing through a pair of source and drain contact metal structures, the upper portion of each of the source and drain contact metal structures has a first lateral width and the lower portion of each of the source and drain contact metal has a second lateral width, larger than the first lateral width.

3. The apparatus of claim 2, wherein the second lateral width is larger than the first lateral width by twice a lateral thickness of the intervening dielectric material.

4. The apparatus of claim 2, wherein, within a second plane orthogonal to the first plane, the upper portion of each of the pair of source and drain contact metal structures has a first lateral length and the lower portion of the source and drain contact metal structures has a second lateral length, larger than the first lateral length.

5. The apparatus of claim 2, wherein:
the gate comprises a metal structure of a first height above a first the channel material layers;
the lower portion of the pair of source and drain contact metal structures has a second height above the first of the channel material layers;
the second height is no greater than the first height.

6. The apparatus of claim 5, wherein:
the gate spacer material layer extends to a third height above the first of the channel material layers; and
the upper portion of the pair of source and drain contact metal structures have at least the third height.

7. The apparatus of claim 6, further comprising a gate capping dielectric material over the gate and having at least the third height, wherein the gate spacer material is between a sidewall of the gate capping dielectric material and the intervening dielectric material.

8. The apparatus of claim 7, wherein a top surface of the gate capping dielectric material is coplanar with a top surface of the upper portion of the source and drain contact metal structures.

9. The apparatus of claim 1, wherein the gate spacer material has a first dielectric composition and wherein the intervening dielectric material has a second dielectric composition comprising more carbon or nitrogen than the first dielectric composition.

10. The apparatus of claim 1, wherein the lower and upper portions of the source or drain contact metal structure have substantially the same chemical composition.

11. The apparatus of claim 1, further comprising a first via contacting the gate and a second via contacting the source or drain contact metal structure, wherein the first via is deeper than the second via.

12. An integrated circuit (IC) structure, comprising:
a plurality of transistor channel layers;
a gate adjacent to, and between, individual ones of the channel layers;
a gate spacer material layer adjacent to a sidewall of the gate;
a source or drain contact metal structure coupled to the channel layers, wherein:
a lower portion of the source or drain contact metal structure has a first lateral width;
an upper portion of the source or drain contact metal structure has a second lateral width;
and the second lateral width is smaller than the first lateral width by at least a thickness of an intervening dielectric material that is between the gate spacer material layer and upper portion of the source or drain contact metal structure.

13. The IC structure of claim 12, wherein:
the second lateral width is smaller than the first lateral width by at least twice the thickness of the intervening dielectric material;
the gate comprises a metal structure of a first height above a first the channel material layers;
the lower portion of the source or drain contact metal structure has a second height above the first of the channel material layers;
the second height is no greater than the first height.

14. The IC structure of claim 13, further comprising a first via of a first depth in contact with the metal structure of the gate at the first height and a second via of a second depth in contact with the upper portion of the source or drain contact metal, wherein the first depth is greater than the second depth.

15. The IC structure of claim 12, wherein the intervening dielectric material has a different chemical composition than the gate spacer material layer.

16. The IC structure of claim 15, wherein the intervening dielectric material has lateral thickness less than a lateral distance between the intervening dielectric material and the sidewall of the gate.

17. A method, comprising:
receiving a workpiece comprising a metal gate structure adjacent to, and between, a plurality of stacked channel material layers;
exposing a sidewall of a gate spacer material layer adjacent to a sidewall of the metal gate structure by recessing a top surface of a pair of source and drain contact metal structures;
depositing a dielectric material liner upon the sidewall of the gate spacer material;
exposing the top surface of the pair of source and drain contact metal structures by anisotropically etching the dielectric material liner; and
augmenting the pair of source and drain contact metal structures by depositing additional contact metal in direct contact with the top surface of the pair of source and drain contact metal structures and in direct contact with a sidewall of the dielectric material liner.

18. The method of claim 17, further comprising depositing a mask material over the dielectric material liner before anisotropically etching the mask material and the dielectric material liner.

19. The method of claim 17, further comprising planarizing a top surface of the source and drain contact metal with a top surface of a dielectric material over the metal gate structure.

20. The method of claim 17, wherein the pair of source and drain contact metal structures comprise one or more metals and wherein depositing the additional contact metal comprises depositing the same one or more metals.
